(19) United States
(12) Patent Application Publication
(10) Pub. No.: US 2008/0081477 A1
(43) Pub. Date: Apr. 3, 2008

(54) Method for forming a semiconductor device having a cylindrical hole in a dielectric film

(75) Inventor: Takenobu Ikeda, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/905,073

(22) Filed: Sep. 27, 2007

(30) Foreign Application Priority Data
Sep. 28, 2006 (JP) 2006-263735

(51) Int. Cl. H01L 21/311

(52) U.S. Cl. 438/694; 257/E21.249

(57) ABSTRACT

Anisotropic dry etching uses a hard mask as an etching mask and a mixture of fluorocarbon, oxygen and rare gas as an etching gas, and effects etching of a dielectric film and deposition of deposits on the hard mask for suppressing reduction of the thickness of the hard mask. A higher deposition rate of the deposits is employed during the middle stage of the etching than during the initial stage and final stage of the etching. The higher deposition rate suppresses the reduction of the remaining thickness of the hard mask especially during the middle stage.

This application is based upon and claims the benefit of priority from Japanese patent application No. 2006-263735, the disclosure of which is incorporated herein in its entirety by reference.

### BACKGROUND OF THE INVENTION

(a) Field of the Invention

The present invention relates to a method for manufacturing a semiconductor device having a cylindrical hole in a dielectric film and, more particularly, to a technique of anisotropic etching for forming a cylindrical hole in a dielectric film.

(b) Description of Related Art

DRAM (dynamic random access memory) devices include an array of memory cells each configuring a storage unit for storing therein a binary data. The memory cell includes a MOSFET (metal-oxide-semiconductor field-effect-transistor) formed in a surface region of a semiconductor substrate and a storage capacitor connected to the MOSFET, and stores therein data by storing electric charge in the capacitor via the MOSFET. A larger depth of the cylindrical hole is desirable for providing a larger capacitance for the storage capacitor.

Along with development of a finer design rule of the DRAM devices, the area occupied by a unit memory cell on the silicon substrate has been drastically reduced. Thus, a cylindrical capacitor is generally employed as the storage capacitor in a DRAM device for assuring a specific capacitance while reducing the occupied area thereof. The cylindrical capacitor is formed using the steps of forming a cylindrical hole in a thick dielectric film overlying the silicon substrate, and consecutively forming a bottom electrode, a capacitor insulation film and a top electrode on the bottom and sidewall of the cylindrical hole.

The thick dielectric film including silicon oxide is generally patterned to form therein the cylindrical holes by a dry etching technique using a hard mask such as made of amorphous carbon. The dry etching uses, as the etching gas, a mixture of gases including fluorocarbon, such as C₄F₈, C₅F₈ and C₄F₆, oxygen (O₂) and rare gas such as argon (Ar) and xenon (Xe). The fluorocarbon is dissociated to generate carbon radicals, fluoride radicals, CF radicals etc., whereby the fluorine radicals and CF radicals react with silicon oxide to proceed with the etching.

On the other hand, the carbon radicals are deposited to configure carbon-containing deposits on the wafer surface to protect the hard mask. This prevents the hard mask from being etched to reduce the thickness thereof during the etching. The O₂ gas generates therefrom oxygen radicals, which react with the carbon radicals to thereby reduce the deposition rate of the carbon-containing deposits. This allows adjustment of the ratio of O₂ gas to the total etching gas to control the deposition rate of the deposits.

The cylindrical hole receiving therein the capacitor generally has a smaller diameter and a larger depth, along with the reduction in the occupied area of the memory cell, the larger depth assuring the effective surface area of the electrodes in the smaller occupied area of the cylindrical hole. Thus, the aspect ratio of the cylindrical hole increases, and the etching time length of the dry etching significantly increases. On the other hand, the reduction of the diameter of the cylindrical hole restricts the thickness of the hard mask having a corresponding opening, whereby it is generally difficult to assure the sufficient remaining thickness of the hard mask until the end of the dry etching.

If the sufficient remaining thickness of the hard mask is not assured until the end of the etching, a side etching proceeds in the cylindrical holes, as shown in FIG. 4, to form a bowing 20 on the sidewall of the cylindrical holes 18 formed in the thick dielectric film 14. It is to be noted that the cylindrical holes 18 are arranged with a high density wherein the gap between adjacent cylindrical holes 18 is extremely small. To assure a sufficient gap and thereby prevent a short-circuit failure between the adjacent holes 18, the remaining thickness of the hard mask 15 should be assured until the end of the etching.

In order to secure the sufficient thickness of the hard mask 15 until the end of the etching, it is possible to perform the etching under the condition of a higher deposition rate of the carbon-containing deposits as described above. The condition of the higher deposition rate allows the deposits 19 on the hard mask 15 to have a sufficient amount, thereby suppressing the etching of the hard mask 15. However, as shown in FIG. 5 in this case, the deposits 18a are also accumulated on the bottom of the cylindrical holes 18 so that the deposition rate of the deposits may excel the etching rate of the silicon oxide to thereby cause an etch stop wherein the proceeding of the etching is stopped. In short, securing of the remaining thickness of the hard mask and prevention of the etch stop have therebetween the relationship of a trade-off.

Patent Publication JP-2002-110647A describes a technique for raising the deposition rate of the carbon-containing deposits in a stepwise manner by a stepwise reduction of the flow rate of O₂ in the etching gas during a dry etching for forming a through-hole having a higher aspect ratio.

During the etching to form any holes having a high aspect ratio, the deposits are hardly accumulated on the bottom of the holes at the last stage of the etching, i.e., near the bottom of the thick dielectric film, whereby the etch stop hardly occurs at the last stage. In view of this fact, the above publication employs the stepwise increase of the deposition rate to assure the sufficient remaining thickness of the hard mask until the end of the etching without incurring the etch stop.

However, it is desired that the cylindrical hole receiving therein the capacitor have a higher aspect ratio along with a further reduction in the occupied area of the memory cell. Thus, there is an endless desire to effectively suppress the etch stop while assuring the sufficient thickness of the hard mask and prevention of the bowing during the dry etching for forming the cylindrical hole receiving therein the capacitor.

### SUMMARY OF THE INVENTION

In view of the above, it is an object of the present invention to provide a method for manufacturing a semiconductor device, which is capable of forming a cylindrical hole having a higher aspect ratio while preventing occurring of the etch stop.

The present invention provides a method for manufacturing a semiconductor device, including: forming a dielectric film overlying a semiconductor substrate; and patterning the dielectric film by an anisotropic etching using an etching mask and an etching gas to form a hole in the dielectric film, the dry etching effecting both selective etching of the dielectric film and depositing deposits at least on the etching mask and within the hole, the anisotropic etching having a deposition rate of the deposits, which is higher during a middle stage of the anisotropic etching than during initial and final stages of the anisotropic etching.

The above and other objects, features and advantages of the present invention will be more apparent from the following description, referring to the accompanying drawings.

### BRIEF DESCRIPTION OF THE DRAWINGS

FIGS. 1A to 1D are sectional views of a semiconductor device in consecutive steps of a fabrication process including an anisotropic etching according to an embodiment of the present invention.

FIG. 2 is a graph showing the relationship between the flow rate of O₂ and the etching time length in the anisotropic etching.

FIG. 3 is a graph showing the relationship between the ratio of O₂ to the total etching gas and the etching depth (or etching time length).

FIG. 4 is a sectional view of a conventional semiconductor device, showing a problem occurring in the dry etching for forming cylindrical holes.

FIG. 5 is a sectional view of another conventional semiconductor device, showing another problem occurring in the dry etching for forming cylindrical holes.

### PREFERRED EMBODIMENT OF THE INVENTION

Now, an exemplary embodiment of the present invention will be described with reference to accompanying drawings, wherein similar constituent elements are designated by similar reference numerals throughout the drawings.

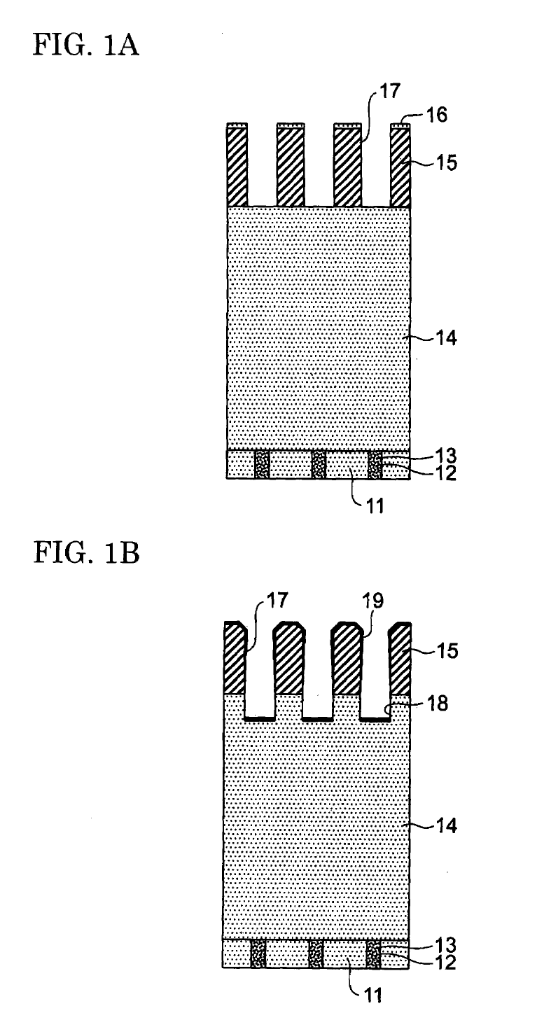

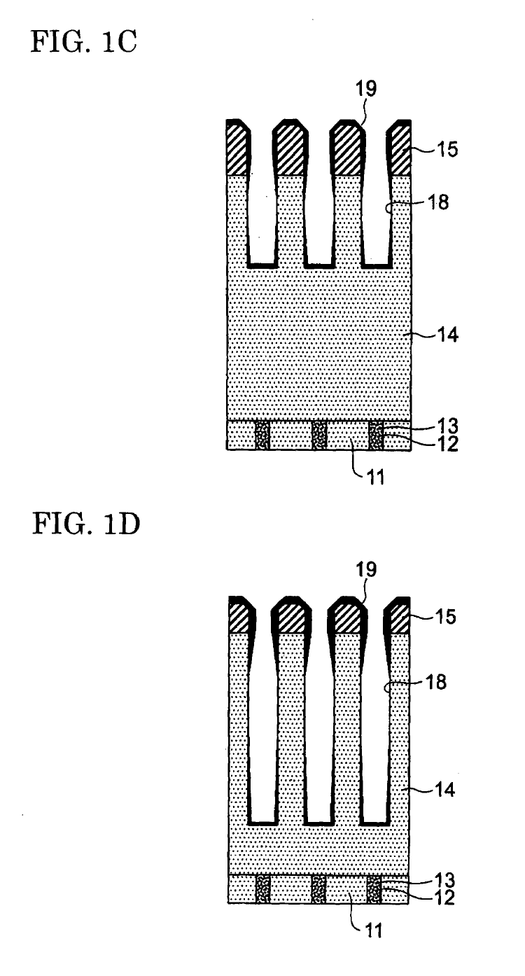

FIGS. 1A to 1D are sectional views of a semiconductor device, showing consecutive steps of an anisotropic etching in a fabrication process according to an embodiment of the present invention. Although not illustrated, the fabrication process includes the following steps before the step shown in FIG. 1A. MOSFETs are formed in the surface region of a silicon substrate underlying the structure shown in FIG. 1A. The MOSFETs each include a gate electrode overlying the silicon substrate with an intervention of a gate insulating film, and source/drain regions disposed adjacent to the gate electrode in the surface region of the silicon substrate.

A first interlayer dielectric film (not shown) is deposited on the gate electrode, and patterned to have therein contact holes receiving therein contact plugs, which connect to the source/drain regions. Thereafter, bit lines are formed on the first interlevel dielectric film to connect to the contact plugs. A second interlevel dielectric film 11, shown in FIG. 1A, is deposited on the first interlevel dielectric film to a thickness of 700 nm, and patterned to have therein through-holes 12, which expose therethrough the top of the contact plugs. The through-holes 12 have a diameter of 100 nm, for example. Via-plugs 13 are then formed by depositing an impurity-doped polysilicon film within the through-holes 12.

After depositing a thick insulation film 14 on the second interlayer dielectric film 11 and the via-plugs 13 to a thickness of 3 micrometers, an amorphous carbon film, which is later to configure a hard mask 15, is formed on the thick insulation film 14. A 80-nm-thick insulating film is formed thereon and patterned to configure a film pattern 16 having elliptical openings 17 disposed corresponding to the via-plugs 13. Subsequently, the amorphous carbon film is patterned using the film pattern 16 as an etching mask to form the hard mask 15, thereby obtaining the structure shown in FIG. 1A. The thickness of the hard mask 15 is about 800 nm, and the diameter of the elliptical openings 17 in the hard mask 15 is roughly 150 nm.

Thereafter, a dry etching process using the hard mask 15 as an etching mask is performed to form cylindrical holes 18 in the thick insulation film 14, the cylindrical holes 18 exposing therethrough the top of via-plugs 13 and being sometimes referred to as capacitor receiving holes hereinafter.

An RIE (reactive ion etching) system, for example, which includes parallel planar electrodes and two RF power sources (excitation power sources), is used for the dry etching. The RIE system includes an etching chamber receiving therein a planar top electrode and a planar bottom electrode disposed parallel to one another. The top electrode configures a drive electrode for supplying a high-frequency power, whereas the bottom electrode configures a susceptor for mounting thereon a semiconductor wafer and provides a bias-frequency power. Adjustment of the drive-frequency power controls generation and dissociation of plasma, whereas adjustment of the bias-frequency power controls the acceleration energy of the ions impinging onto the semiconductor wafer. Both the adjustments are conducted independently of each other.

The etching gas in the dry etching includes a mixture of C₄F₆, C₄F₈, O₂, Ar, and Xe. The total pressure is set at 30 mTorr, an electric power of 2000 W is supplied from the drive-frequency power source, and an electric power of 3000 W is supplied from the bias-frequency power source. Gas flow rates of C₄F₆, C₄F₈, Ar and Xe are 5 sccm, 20 sccm, 110 sccm and 110 sccm, respectively.

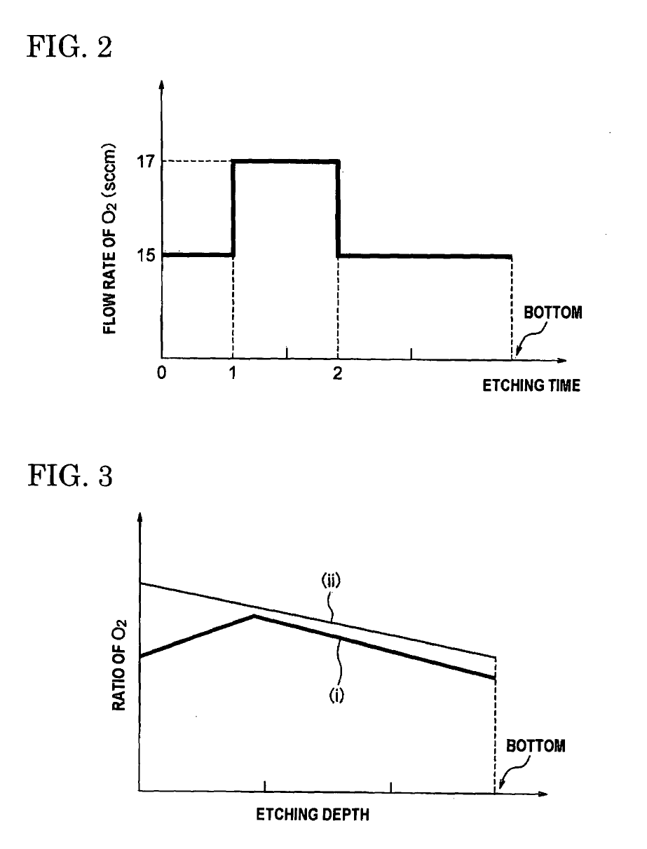

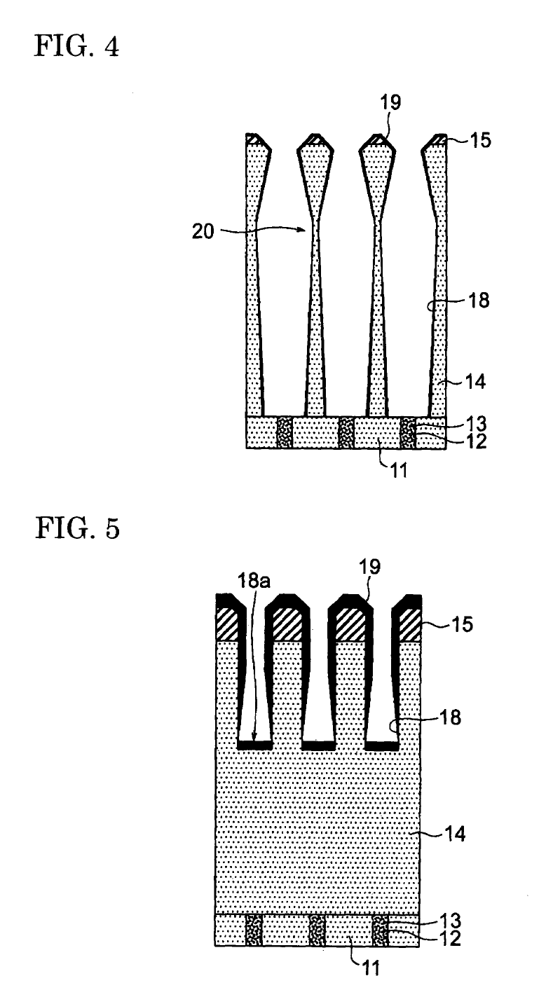

The dry etching process for forming the capacitor receiving holes 18 hardly encounters an etch stop at the initial stage of the etching, i.e., etching at the top portion of the interlevel dielectric film 14 and the final stage of the etching, i.e., etching at the bottom portion of the interlevel dielectric film 14. The dry etching process frequently encounters an etch stop at the middle stage of the etching, i.e., at the central portion of the interlevel dielectric film. In view of this fact, the flow rate of O₂ is changed between adjacent stages of the etching. A higher flow rate of O₂ provides a higher etching rate in the dry etching. FIG. 2 shows an example of the control of flow rate of O₂ during the dry etching, wherein the flow rate of O₂ is plotted along the etching time length.

As shown in FIG. 2, the flow rate is fixed at a lower rate of 15 sccm during the initial stage between the start of etching and a time instant of one minute elapsed from the start, and also during the final stage between a time instant of two minutes elapsed from the start and the end of the etching. The flow rate of O₂ is fixed at a higher rate of 17 sccm during the middle stage between the time instant of one minute and the time instant of two minutes.

FIG. 1B shows the initial stage of the dry etching, wherein deposits 19 are accumulated uniformly on top of the hard mask 15 and bottom of the then-etched capacitor receiving holes 18. This initial stage provides a smaller amount of deposits 19, because of a smaller amount of the etched material, and causes a less possibility of the etch stop. Thus, the flow rate of O₂ is fixed at a lower rate in FIG. 2. The initial stage of the etching proceeds to an etching depth of about 700 nm during the one minute of etching while providing a suitable amount of deposits 19 to suppress reduction of the thickness of the hard mask 15.

FIG. 1C shows the middle stage of the dry etching, wherein deposits are accumulated on the bottom of the then-etched capacitor receiving holes 18 in a larger amount to reduce the etch rate. For preventing occurrence of the etch stop, it is generally necessary that the etched amount excel the amount of deposits. Thus, the flow rate of O₂ is raised up to 17 sccm, as shown in FIG. 2, to reduce the deposition rate. The middle stage of the etching proceeds to an etching depth of about 1400 nm during the one minute of etching.

FIG. 1D shows the final stage of etching, wherein the deposits 19 are less accumulated on the bottom of the then-etched capacitor receiving holes 18, because a less amount of the etched material reaches the bottom of the then-etched capacitor receiving holes 18. Thus, the deposition rate can be raised during the final stage without causing the etch stop, by reducing the flow rate of O₂ as shown in FIG. 2. This final stage of the etching proceeds to the end of etching until the interlevel dielectric film 11 and via plugs 13 are exposed at the bottom of the etched holes 18. A suitable amount of deposits 19 is accumulated on the hard mask 15 to thereby prevent reduction of the thickness of the hard mask 15.

The change of flow rate of O₂ may be performed without breaking the anisotropic etching between the stages, or may be performed during a temporary stop of the anisotropic etching. The capacitor receiving holes 18 thus formed have a depth of around 3 micrometers and a diameter of about 150 nm, thereby having an aspect ratio of around 20. After the capacitor receiving holes 18 are formed, bottom electrode film, capacitor insulation film and top electrode film are consecutively deposited to configure the cell capacitors within the capacitor receiving holes 18. By additionally forming overlying interconnections etc., the final structure of the semiconductor device is obtained.

In the method of the above embodiment, the flow rate of O₂ is reduced during the initial stage of etching where the etch stop hardly occurs, to thereby raise the deposition rate of the deposits and obtain a suitable amount of deposits for preventing reduction of the thickness of the hard mask. On the other hand, the flow rate of O₂ is raised during the middle stage of etching where the etch stop is likely to occur, to thereby reduce the rate of deposition and thus enhance the etching.

The above process achieves both prevention of reduction in the thickness of hard mask, and prevention of occurring of the etch stop during the dry etching to form a cylindrical hole having a high aspect ratio.

In the above embodiment, the flow rate of O₂ is changed in a stepwise manner as shown in FIG. 2. However, the change of flow rate of O₂ may be performed in a continuous manner or moderately, as depicted by a graph (i) shown in FIG. 3, so long as the flow rate of O₂ is higher during the middle stage of etching compared to the initial stage and the last stage of etching. In FIG. 3, graph (ii) shows the comparative flow rate of O₂ employed in JP-2002-110647A, wherein the flow rate is reduced at a constant rate during all the stages of the etching for obtaining a higher deposition rate of deposits along with the elapse of the etching time.

In the above embodiment, the flow rate of O₂ is controlled to obtain a suitable deposition rate of the deposits. However, the control of flow rate of O₂ may be replaced by a control of another parameter such as by controlling the flow rate of C₄F₆ and C₄F₈ to control the relative flow rate of O₂ or controlling the chamber pressure or RF power of the power sources.

As described hereinabove, the method of the present embodiment achieves the advantage of alleviating the trade-off between the reduction of the thickness of the hard mask used as an etching mask and occurring of the etch stop in the dry etching, to form a cylindrical hole having a high aspect ratio.

If the interlevel dielectric film etched by the dry etching includes silicon oxide, the etching gas may include at least fluorocarbon and oxygen, wherein the relative flow rate of oxygen is increased at a time instant between the initial stage and the middle stage of the etching, and may be reduced at a time instant between the middle stage and the final stage of the etching. The etching gas may further include rage gas such as argon and xenon. A stable dry etching is obtained by a suitable degree of dilution of fluorocarbon providing an etching performance and oxygen providing a depositing performance by using the rare gas.

The present invention is particularly effective for forming a deep hole having an aspect ratio of 15 or above, wherein the control of etch rate is difficult to achieve without incurring an etch stop. The hole to be formed by the dry etching may be a through-hole penetrating the dielectric film or may be a depression having a bottom within the dielectric film.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A method for manufacturing a semiconductor device, comprising:
forming a dielectric film overlying a semiconductor substrate; and
patterning said dielectric film by an anisotropic etching using an etching mask and an etching gas to form a hole in said dielectric film, said dry etching effecting both selective etching of said dielectric film and depositing deposits at least on said etching mask and within said hole,
said anisotropic etching having a deposition rate of said deposits, which is higher during a middle stage of said anisotropic etching than during initial and final stages of said anisotropic etching.

2. The method according to claim 1, wherein said anisotropic etching controls said deposition rate by controlling at least one of flow rate of at least one component of said etching gas, total pressure of said etching gas and RF power during said anisotropic etching.

3. The method according to claim 2, wherein said dielectric film includes silicon oxide, said etching gas includes at least fluorocarbon and oxygen, and a flow rate of said oxygen is higher during said middle stage than during said initial and final stages.

4. The method according to claim 3, wherein said etching gas further includes argon.

5. The method according to claim 3, wherein said flow rate of oxygen is increased or decreased in a stepwise manner or a continuous manner.

6. The method according to claim 1, wherein said hole formed by said dry etching has an aspect ratio of 15 or above.

7. The method according to claim 1, wherein said hole is a through-hole.
